(19) United States
(12) Patent Application Publication
(10) Pub. No.: US 2015/0122177 A1
(43) Pub. Date: May 7, 2015

(54) APPARATUS FOR PROCESSING SUBSTRATE

(71) Applicant: EUGENE TECHNOLOGY CO., LTD., Gyeonggi-do (KR)

(72) Inventors: Il-Kwang Yang, Gyeonggi-do (KR); Byoung-Gyu Song, Gyeonggi-do (KR); Kyong-Hun Kim, Gyeonggi-do (KR); Yong-Ki Kim, Chungcheongnam-do (KR); Yang-Sik Shin, Gyeonggi-do (KR)

(73) Assignee: EUGENE TECHNOLOGY CO., LTD., Gyeonggi-do (KR)

(21) Appl. No.: 14/400,816

(22) PCT Filed: Jun. 14, 2013
(86) PCT No.: PCT/KR2013/005263

§ 371 Date: Nov. 13, 2014

(30) Foreign Application Priority Data
Jun. 20, 2012 (KR) 10-2012-0066080

(51) Int. Cl. H01J 37/32; C23C 16/455; C23C 16/505

(52) U.S. Cl. CPC H01J 37/3211; C23C 16/505; C23C 16/455
USPC 118/723 I

(57) ABSTRACT

Provided is a substrate processing apparatus. The substrate processing apparatus includes a chamber having an opened upper side, the chamber having a passage, through which a substrate is accessible, in a side thereof, a chamber cover covering the opened upper side of the chamber to provide an inner space in which a process with respect to the substrate is performed, the chamber cover having a gas supply hole passing through a ceiling wall thereof, an upper antenna disposed on an upper central portion of the chamber cover to generate an electric field in a central portion of the inner space, the upper antenna generating plasma by using a source gas supplied into the inner space, a side antenna disposed to surround a side portion of the chamber cover to generate an electric field in an edge portion of the inner space, the side antenna generating plasma by using the source gas supplied into the inner space, and a gas supply tube connected to the gas supply hole to supply the source gas into the inner space. The gas supply hole is disposed outside the upper antenna.

### BACKGROUND OF THE INVENTION

The present invention disclosed herein relates to an apparatus for processing a substrate, and more particularly, to a substrate processing apparatus which provides uniform plasma density by using upper and side antennas.

A semiconductor device includes a plurality of layers on a silicon substrate. The layers are deposited on the substrate through a deposition process. The deposition process has several important issues. The issues are important in evaluating deposited layers and selecting a deposition method.

First, one of the important issues may be qualities of the deposited layers. This represents compositions, contamination levels, defect density, and mechanical and electrical properties of the deposited layers. The compositions of the deposited layers may be changed according to deposition conditions. This is very important for obtaining a specific composition.

Second, one of the important issues may be a uniform thickness crossing a wafer. Specifically, a thickness of a layer deposited on a pattern having a nonplanar shape in which a stepped portion is formed is very important. Whether the deposited layer has a uniform thickness may be determined through a step coverage which is defined as a value obtained by dividing a minimum thickness of a layer deposited on the stepped portion by a thickness of a layer deposited on a top surface of a pattern.

The other issue with respect to the deposition may be a filling space. This includes a gap filling in which an insulation layer including an oxide layer is filled between metal lines. The gap is provided for physically and electrically insulating the metal lines from each other.

Among the above-described issues, the uniformity may be one of important issues related to the deposition process. A non-uniform layer may cause high electrical resistance on a metal line to increase possibility of mechanical damage.

### SUMMARY OF THE INVENTION

The present invention provides a substrate processing apparatus that is capable of improving process uniformity over an entire surface of a substrate.

The present invention also provides a substrate processing apparatus that is capable of improving density of plasma.

Further another object of the present invention will become evident with reference to following detailed descriptions and accompanying drawings.

Embodiments of the present invention provide substrate processing apparatuses including: a chamber having an opened upper side, the chamber having a passage, through which a substrate is accessible, in a side thereof; a chamber cover covering the opened upper side of the chamber to provide an inner space in which a process with respect to the substrate is performed, the chamber cover having a gas supply hole passing through a ceiling wall thereof; an upper antenna disposed on an upper central portion of the chamber cover to generate an electric field in a central portion of the inner space, the upper antenna generating plasma by using a source gas supplied into the inner space; a side antenna disposed to surround a side portion of the chamber cover to generate an electric field in an edge portion of the inner space, the side antenna generating plasma by using the source gas supplied into the inner space; and a gas supply tube connected to the gas supply hole to supply the source gas into the inner space, wherein the gas supply hole is disposed outside the upper antenna.

In some embodiments, the substrate processing apparatuses may further includes a ring-shaped block plate that is closely attached to a ceiling surface of the chamber cover to diffuse the source gas toward the substrate, wherein the block plate may include: an opening defined in a center thereof to correspond to the upper antenna; a passage recessed from one surface thereof to face the ceiling surface; and a plurality of gas spray holes communicating with the passage to spray the source gas.

In other embodiments, the passage may include: an inner passage defined along a circumference of the opening to correspond to a central portion of the substrate; and a connection passage connecting the gas supply hole to the inner passage, wherein the gas spray holes may be defined in an inner circumferential surface of the block plate.

In still other embodiments, the passage may include: an inner passage defined along a circumference of the opening to correspond to a central portion of the substrate; and a connection passage connecting the gas supply hole to the inner passage, wherein the gas spray holes may be spaced apart from each other in the inner passage.

In even other embodiments, the gas spray holes may gradually increase in distribution density as the gas spray holes are away from the gas supply hole.

In yet other embodiments, the gas spray holes may gradually increase in diameter as the gas spray holes are away from the gas supply hole.

In further embodiments, the passage may include: an inner passage defined along a circumference of the opening to correspond to a central portion of the substrate; an outer passage defined outside the inner passage; and a plurality of connection passages connecting the inner passage to the outer passage, wherein the gas supply hole may be defined in the outer passage, and the gas spray holes may be respectively defined in the inner passage and the outer passage.

In still further embodiments, the connection passages may gradually increase in width as the connection passages are away from the gas supply hole.

In even further embodiments, the gas spray holes defined in the inner passage may have distribution densities greater than those of the gas spray holes defined in the outer passage.

In yet further embodiments, the gas spray holes defined in the inner passage may have diameters greater than those of the gas spray holes in the outer passage.

In much further embodiments, the passage may include: an inner passage defined along a circumference of the opening to correspond to a central portion of the substrate; an outer passage defined outside the inner passage; and a plurality of connection passages connecting the inner passage to the outer passage, wherein the gas supply hole may be defined in the outer passage, and the gas spray holes may be respectively defined in an inner circumferential surface of the block plate and the outer passage.

In still much further embodiments, the passage may further include a plurality of auxiliary connection passages connecting one side of the outer passage defined in a side opposite to the gas supply hole with respect to the opening to the other side of the outer passage adjacent to the gas supply hole, the plurality of auxiliary connection passages being defined parallel to each other, wherein the connection passages may be parallel to the auxiliary connection passages.

In even much further embodiments, the passage may include: an inner passage defined along a circumference of the opening to correspond to a central portion of the substrate, the inner passage having a semicircular shape and being defined in a side opposite to the gas supply hole with respect to the opening; an outer passage defined outside the inner passage, the outer passage having a semicircular shape and being defined in a side opposite to the inner passage with respect to the opening; a connection passage having one end connected to the gas supply hole and the other end connected to a central portion of the outer passage; and an auxiliary connection passage connecting both ends of the inner passage to both ends of the outer passage, wherein the gas spray holes may be spaced apart from each other in the inner passage and the outer passage.

### BRIEF DESCRIPTION OF THE DRAWINGS

The accompanying drawings are included to provide a further understanding of the present invention, and are incorporated in and constitute a part of this specification. The drawings illustrate exemplary embodiments of the present invention and, together with the description, serve to explain principles of the present invention. In the drawings:

FIG. 1 is a schematic view of a substrate processing apparatus according to an embodiment of the present invention;

FIG. 2 is a view illustrating an inner space of FIG. 1;

FIG. 3 is a cross-sectional view illustrating a block plate of FIG. 1 and a flow of a source gas;

FIG. 4 is a view illustrating a flow of a source gas and plasma that are respectively supplied into and generated in the inner space of FIG. 1;

FIG. 5 is a cross-sectional view illustrating a first modified example of the block plate of FIG. 1 and a flow of the source gas;

FIG. 6 is a cross-sectional view illustrating a second modified example of the block plate of FIG. 1 and a flow of the source gas;

FIG. 7 is a cross-sectional view illustrating a third modified example of the block plate of FIG. 1 and a flow of the source gas;

FIG. 8 is a cross-sectional view illustrating a fourth modified example of the block plate of FIG. 1 and a flow of the source gas;

FIG. 9 is a cross-sectional view illustrating a fifth modified example of the block plate of FIG. 1 and a flow of the source gas; and

FIG. 10 is a view illustrating thickness distribution of a thin film deposited through a substrate processing apparatus according to a related art.

### DETAILED DESCRIPTION OF PREFERRED EMBODIMENTS

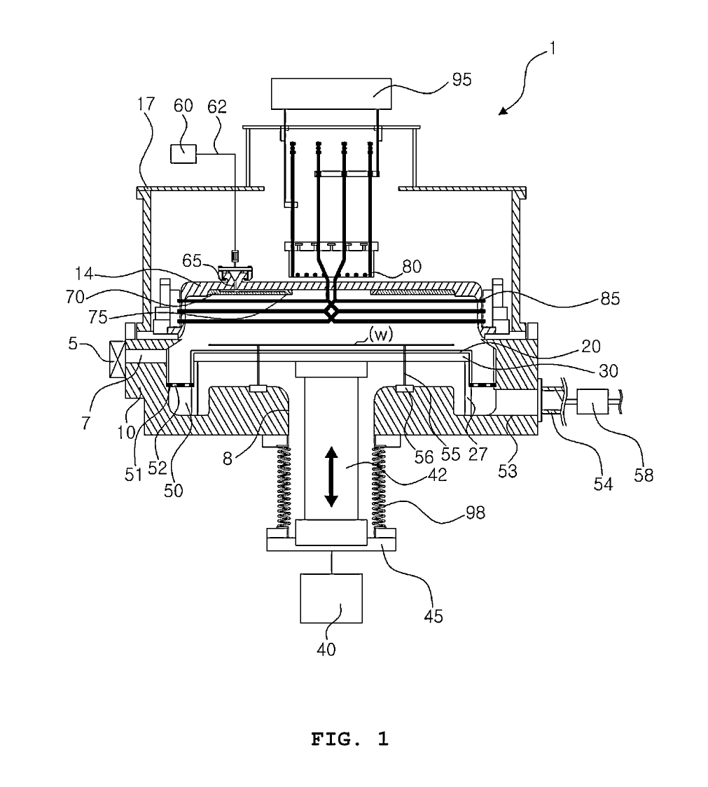

Hereinafter, exemplary embodiments of the present invention will be described in detail with reference to FIGS. 1 to 10. The present invention may, however, be embodied in different forms and should not be constructed as limited to the embodiments set forth herein. Rather, these embodiments are provided so that this disclosure will be thorough and complete, and will fully convey the scope of the present invention to those skilled in the art. In the drawings, the shapes of components are exaggerated for clarity of illustration.

Although an inductively coupled plasma (ICP) type plasma process is described below as an example, the present invention is applicable to various plasma processes. Also, although a substrate is described as an example, the present invention is applicable to various objects to be processed.

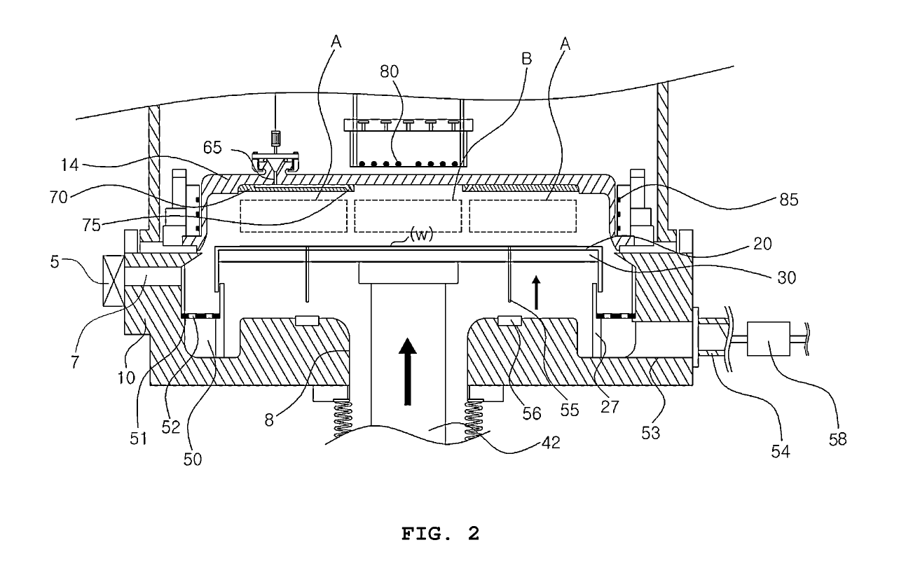

FIG. 1 is a schematic view of a substrate processing apparatus 1 according to an embodiment of the present invention, and FIG. 2 is a view illustrating an inner space of FIG. 1. Referring to FIG. 1, the substrate processing apparatus 1 includes a main chamber 10 and a chamber cover 14. The main chamber 10 has an opened upper side. Also, a passage 7 through which a substrate W is accessible is defined in a side of the main chamber 10. A gate valve 5 is disposed outside the passage 7. The passage 7 may be opened or closed by the gate valve 5.

The chamber cover 14 covers the opened upper side of the main chamber 10 to define an inner space blocked from the outside. The substrate W is loaded into the inner space through the passage 7. Processes with respect to the substrate W may be performed in the inner space.

A susceptor cover 20 is disposed to surround upper and side portions of a susceptor 30. While processes is performed, the substrate W is placed on an upper portion of the susceptor cover 20. The susceptor cover 20 has a ‘ [symbol] ’ shape in section. A lower end of a side portion of the susceptor cover 20 extends toward a lower portion of the susceptor 30. The susceptor 30 has a shape corresponding to that (e.g., a circular shape) of the substrate W. A support shaft 42 is connected to the lower portion of the susceptor 30. Also, the support shaft 42 passes through a through hole 8 defined in a lower portion of the main chamber 10. Also, a fixing ring 45 is connected to a lower end of the support shaft 42. A driving part 40 is connected to the fixing ring 45 to elevate the fixing ring 45 and the support shaft 42. The susceptor 30 is elevated together with the support shaft 42.

A bellows 98 has an upper end connected to a bottom surface of the main chamber 10 and a lower end connected to the fixing ring 45. The support shaft 42 is connected to the fixing ring 45 through the inside of the bellows 98. The bellows 98 prevents a source gas supplied into the inner space from leaking to the outside through the through hole 8 as well as prevents a vacuum atmosphere formed in the inner space from being broken.

As shown in FIGS. 1 and 2, lift pins 55 supports the substrate W loaded on an upper portion of the susceptor 30. The lift pins 55 are disposed in guide holes (not shown) passing through the susceptor 30 and the susceptor cover 20. Thus, as the susceptor 30 is elevated, the lift pins 55 move along the guide holes.

As shown in FIG. 1, in a state where the susceptor 30 descends, a lower end of each of the lift pins 55 is supported by a support plate 56 disposed on the bottom surface of the main chamber 10, and an upper end of each of the lift pins 55 protrudes from a top surface of the susceptor cover 20. Here, the lift pins 55 support the loaded substrate W. As shown in FIG. 2, in a state where the susceptor 30 ascends, the lower end of each of the lift pins 55 is spaced apart from the support plate 56, and the upper end of each of the lift pins 55 is substantially flush with the top surface of the susceptor cover 20. Here, the substrate W is placed on the top surface of the susceptor cover 20, and the processes with respect to the substrate W are performed in a state where the susceptor 30 ascends.

An upper antenna 80 is disposed on an upper central portion of the chamber cover 14, and a side antenna 85 is disposed to surround a side portion of the chamber cover 14. The upper antenna 80 may have a spiral shape and be disposed at substantially the same height. Also, the side antenna 85 may have a spiral shape and be disposed along a height direction of the chamber cover 14. A gas supply hole 65 passes through a ceiling wall of the chamber cover 14. Also, the gas supply hole 65 is defined outside the upper antenna 80 to prevent the gas supply hole 65 from interfering with the upper antenna 80. A gas supply tube 62 is connected to the gas supply hole 65. A gas storage tank 60 in which the source gas is stored is connected to the gas supply hole 65 through the gas supply tube 62. The source gas is supplied into the inner space through the gas supply hole 65. The upper antenna and the side antenna 85 form electric fields in the inner space to generate plasma by using the source gas.

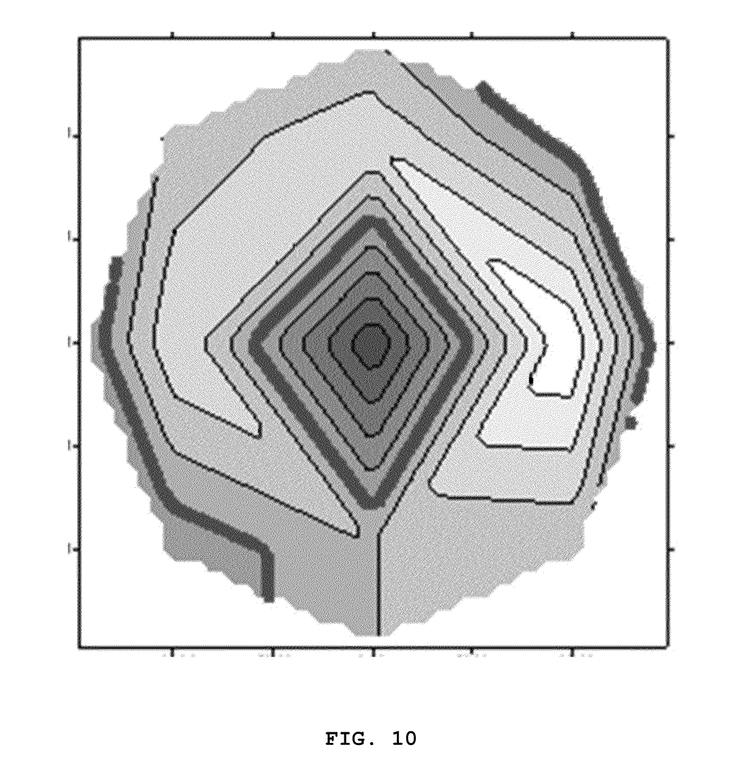

FIG. 10 is a view illustrating thickness distribution of a thin film deposited through a substrate processing apparatus according to a related art. In recent, as a large-scaled substrate W having a size of about 300 mm (about 12 inches) to about 450 mm (about 18 inches) is manufactured, the main chamber 10 and the chamber cover 14 are increasing in size. Thus, it may be difficult to form uniform electric fields within the inner space. In addition, the density of plasma may be non-uniformly distributed. That is, the electric fields may be non-uniformly formed to cross a central portion and an edge portion of the inner space. Thus, as shown in FIG. 10, a thin film deposited on a substrate W by using plasma may be non-uniform. Also, the thin film deposited on the substrate W may have different thicknesses on the central portion and the edge portion of the substrate W.

An electric field generated through the upper antenna 80 is concentrated into a central portion B of the inner space, and an electric field generated through the side antenna 85 is concentrated into an edge portion A of the inner space. Thus, uniform electric fields may be generated within the inner space. Each of the upper and side antennas 80 and 85 may be changed in shape according to the electric fields formed in the central portion B and the edge portion A.

The upper antenna 80 and the side antenna 85 are connected to an RF generator through a matcher 95. Also, the upper and side antennas 80 and 85 form the electric fields by using RF current. The RF current supplied into the upper and side antennas 80 and 85 may vary according to the intensity of desired electric fields. Alternatively, different RF current may be supplied into the upper and side antennas 80 and 85, respectively. A housing 17 may be disposed above the main chamber 10. Also, the matcher 95 may be disposed above the housing 17.

As shown in FIG. 1, an auxiliary bar 27 stands up in a state where a lower end thereof is fixed to the bottom surface of the main chamber 10 and is spaced apart form a sidewall of the main chamber 10. As shown in FIG. 2, when the susceptor 30 ascends, the susceptor cover 20 is disposed on a position lower than that of an upper end of the auxiliary bar 27. While the processes are performed, a lower portion of the susceptor 30 may be isolated from the inner space through the side portion of the susceptor cover 20 and the auxiliary bar 27. Thus, it may prevent plasma and reaction byproducts that are will be described later from moving into the through hole 8 through the lower portion of the susceptor 30.

The auxiliary bar 27 has a stepped portion at a middle height thereof. A baffle 51 is disposed on a stepped portion disposed on the sidewall of the main chamber 10 and the stepped portion of the auxiliary bar 27. The baffle 51 is disposed in a substantially horizontal direction. Also, the baffle 51 has a plurality of exhaust holes 52. The main chamber 10 has an exhaust port 53, and the exhaust port 53 is disposed on the sidewall opposite to the passage 7. An exhaust line 54 is connected to the exhaust port 53, and an exhaust pump 58 is disposed on the exhaust line 54. The plasma and reaction byproducts generated within the inner space are exhausted to the outside through the exhaust port 53 and the exhaust line 54. Here, the exhaust pump 58 forcibly exhausts the plasma and reaction byproducts. The plasma and reaction byproducts are introduced into the exhaust port 53 through exhaust holes 52 of the baffle 51.

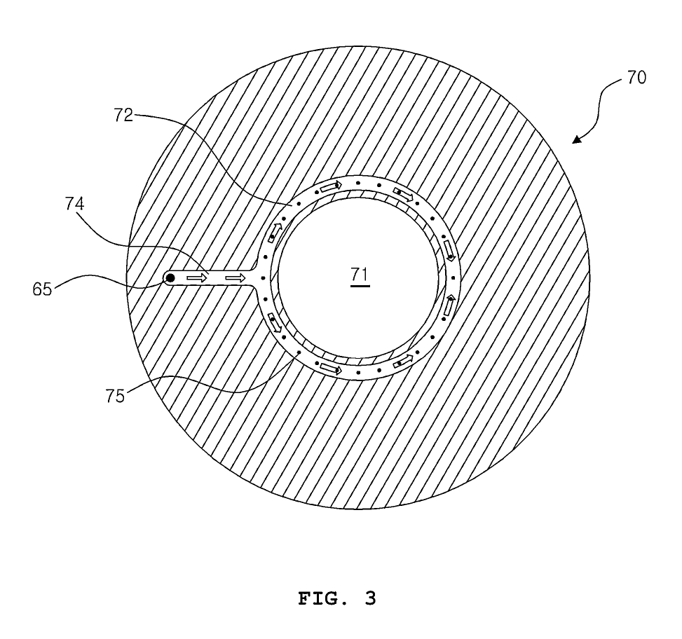

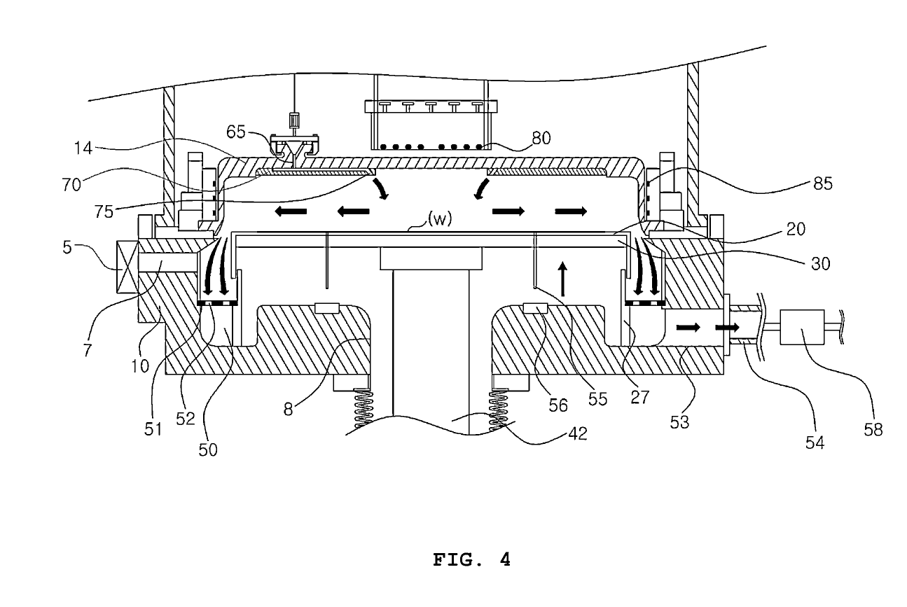

FIG. 3 is a cross-sectional view illustrating a block plate of FIG. 1 and a flow of a source gas, and FIG. 4 is a view illustrating a flow of a source gas and plasma that are respectively supplied into and generated in the inner space of FIG. 1. As described above, the source gas is supplied into the inner space of the main chamber 10 through the gas supply hole 65. Then, the upper and side antennas 80 and 85 respectively generate electric fields in the central and edge portions of the inner space to generate plasma by using the source gas. As shown in FIG. 4, the generated plasma reacts with a surface of the substrate W to deposit a thin film on the substrate W. Here, the plasma and reaction byproducts move into the exhaust port 53 through the baffle 51 and then are exhausted to the outside.

Here, an exhaust space 50 is defined by being recessed from the bottom surface of the main chamber 10. Here, the exhaust space 50 is defined in a circular shape along a lower edge portion of the main chamber 10. Since the exhaust space 50 is defined by the sidewall of the main chamber 10, the baffle 51, and the auxiliary bar 27, a portion of the exhaust space 50 may be blocked from the outside. The plasma and reaction byproducts moves into the exhaust space 50 through the baffle 51 and then moves into the exhaust port 53 along the exhaust space 50. Thus, as shown in FIG. 4, a flow direction of the plasma and reaction byproducts on the surface of the substrate W may be radially formed from a central portion of the substrate W toward an edge portion.

A block plate 70 is closely attached to a ceiling surface of the chamber cover 14 to diffuse the source gas discharged through the gas supply hole 65 onto the surface of the substrate W. The block plate 70 has a plurality of gas spray holes 75. Thus, the source gas is diffused through the gas spray holes 75. As shown in FIG. 3, the block plate 70 has a ring shape having an opening 71 in a central portion thereof. The opening 71 may have substantially the same diameter as that of the central portion B of the inner space (or a diameter of the upper antenna 80).

As shown in FIGS. 2 and 3, the block plate 70 has a passage that is recessed from one surface corresponding to the ceiling surface of the chamber cover 14. The passage includes an inner passage 72 and a connection passage 74. The inner passage 72 has a circular shape defined along a circumference of the opening 71. Also, the inner passage 72 is disposed maximally adjacent to the opening 71 so that the source gas is sprayed toward the central portion of the substrate W. The connection passage 74 has a linear shape that connects the gas supply hole 65 to the inner passage 72.

Since the block plate 70 is closely attached to the ceiling surface of the chamber cover 14, the passage is blocked from the outside. Thus, the source gas supplied through the gas supply hole 65 flows along the passage. The gas spray holes 75 are spaced apart from each other above the inner passage 72. Also, the gas spray holes 75 may be inclined toward the central portion (or a center) of the substrate W. The source gas is sprayed through the gas spray holes 75. The sprayed source gas may move toward the central portion of the substrate W. As described above, since the flow direction of the plasma and reaction byproducts on the surface of the substrate W is radially formed from the central portion of the substrate W toward the edge portion, the sprayed source gas (or the plasma generated through the electric fields) flows from the central portion toward the edge portion on the surface of the substrate W. Thus, the plasma may uniformly react with the surface of the substrate W to deposit a uniform thin film on the substrate of the substrate W.

Unlike FIG. 3, the gas spray holes 75 may be deformed according to distances spaced apart from the gas supply hole 65 (or an end of the connection passage 74 connected to the inner passage 72). That is, the source gas may gradually increase in pressure along the inner passage 72 as the source gas approaches the gas supply hole 65, and the source gas may gradually decrease in pressure along the inner passage 72 as the source gas is away from the gas supply hole 65. Also, the gas spray holes 75 may gradually increase in distribution density as the gas spray holes 75 are away from the gas supply hole 65, and the gas spray holes 75 may gradually increase in diameter as the gas spray holes 75 are away from the gas supply hole 65. Since the source gas gradually decreases in pressure as the gas spray holes 75 are away from the gas supply hole 65, an amount of source gas supplied into the inner space may be uniformly regulated through differences in the distribution density and diameter.

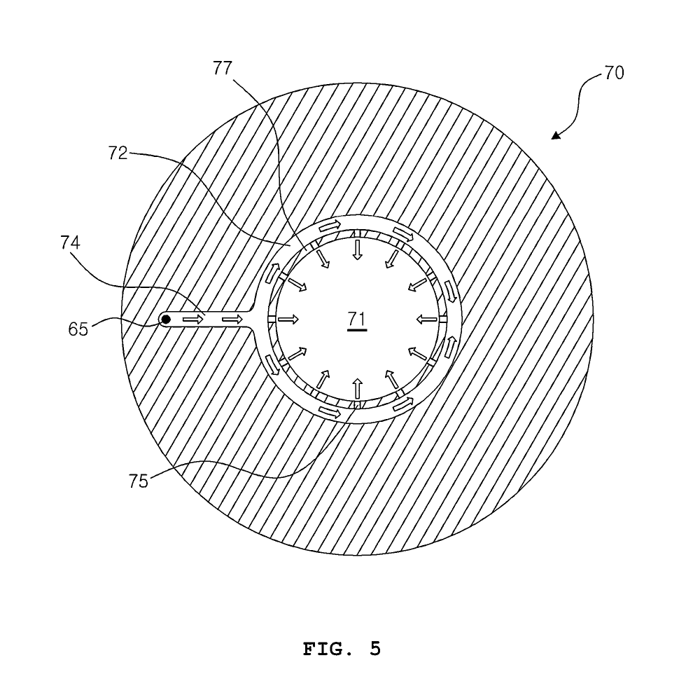

FIG. 5 is a cross-sectional view illustrating a first modified example of the block plate of FIG. 1 and a flow of the source gas. Hereinafter, only features different from those according to the foregoing embodiment will be described. Thus, omitted descriptions herein may be substituted for the above-described contents. As shown in FIG. 5, gas spray holes 75 may be defined in a partition wall 77 (or an inner circumferential surface) between an opening 71 and an inner passage 72. Thus, a source gas is sprayed through the opening 71 to generate plasma in the opening 71 by an upper antenna 80. Then, the plasma moves from the opening 71 toward each of central and edge portions of a substrate W. Thus, the plasma may uniformly react with a surface of the substrate W to deposit a uniform thin film on the surface of the substrate W. As described above, the gas spray holes 75 may gradually increase in distribution density as the gas spray holes 75 are away from a gas supply hole 65. Also, the gas spray holes 75 may gradually increase in diameter as the gas spray holes 75 are away form the gas supply hole 65.

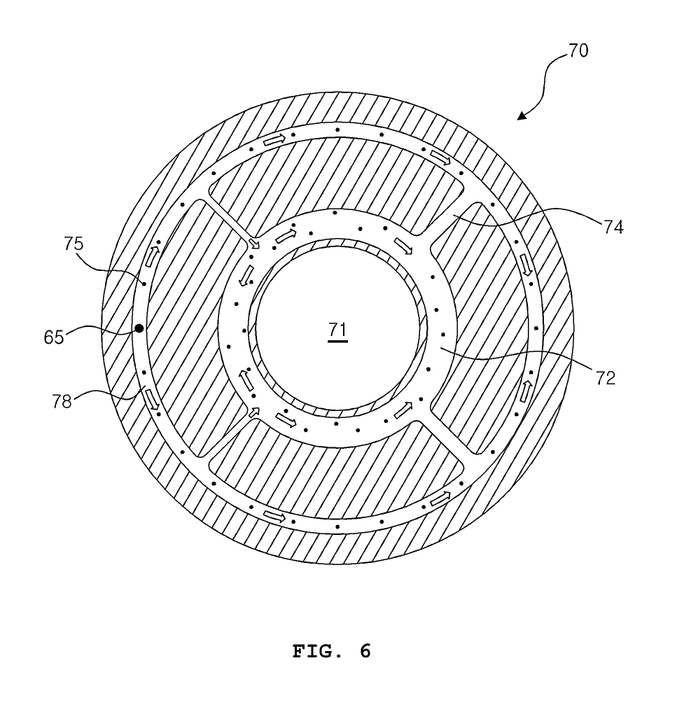

FIG. 6 is a cross-sectional view illustrating a second modified example of the block plate of FIG. 1 and a flow of the source gas. Hereinafter, only features different from those according to the foregoing embodiment will be described. Thus, omitted descriptions herein may be substituted for the above-described contents. Referring to FIG. 6, a passage further includes an outer passage 78 having a circular shape and defined outside an inner passage 72. The gas supply hole 65 is defined in the outer passage 78. A connection passage 74 has a linear shape that connects the inner passage 72 to the outer passage 78. Also, the connection passage 74 is radially defined with respect to a center of an opening 71.

Gas spray holes 75 are spaced apart from each other in the inner and outer passages 72 and 78. The gas spray holes 75 defined in the inner passage 72 may be inclined toward a central portion (or a center) of a substrate W. A source gas moves toward the central portion of the substrate W through the gas spray holes 75 defined in the inner passage 72. Also, the source gas may flow from the central portion toward an edge portion on a surface of the substrate W. Also, the source gas may move toward the edge portion of the substrate W through the gas spray holes 75 defined in the outer passage 75.

The inner passage 72 may have a width greater than that of the outer passage 78. Also, an amount of source gas supplied through the gas spray holes 75 defined in the inner passage 72 may be greater than that of source gas supplied through the gas spray holes 75 defined in the outer passage 72. Thus, an amount of source gas supplied toward the central portion of the substrate W may be compensated.

Also, the connection passage may have a width gradually increasing from a portion adjacent to the gas supply hole 65 toward a portion away from the gas supply hole 65. The gas spray holes 75 may have gradually increase in distribution density as the gas spray holes 75 are away from the gas supply hole 65. Also, the gas spray holes 75 may gradually increase in diameter as the gas spray holes 75 are away form the gas supply hole 65.

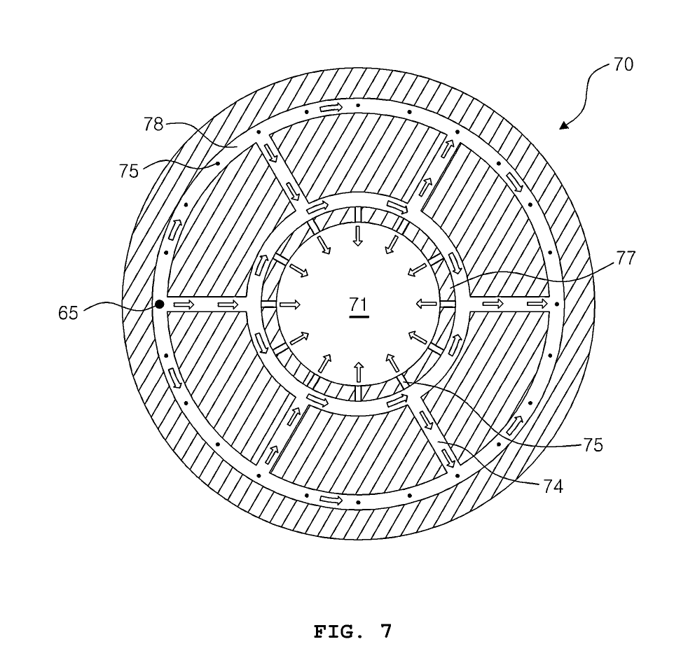

FIG. 7 is a cross-sectional view illustrating a third modified example of the block plate of FIG. 1 and a flow of the source gas. Hereinafter, only features different from those according to the foregoing embodiment will be described. Thus, omitted descriptions herein may be substituted for the above-described contents. Unlike FIG. 6, gas spray holes 75 defined in an inner passage 72 may be defined in a partition wall 77 (or an inner circumference surface) between an opening 71 and the inner passage 72.

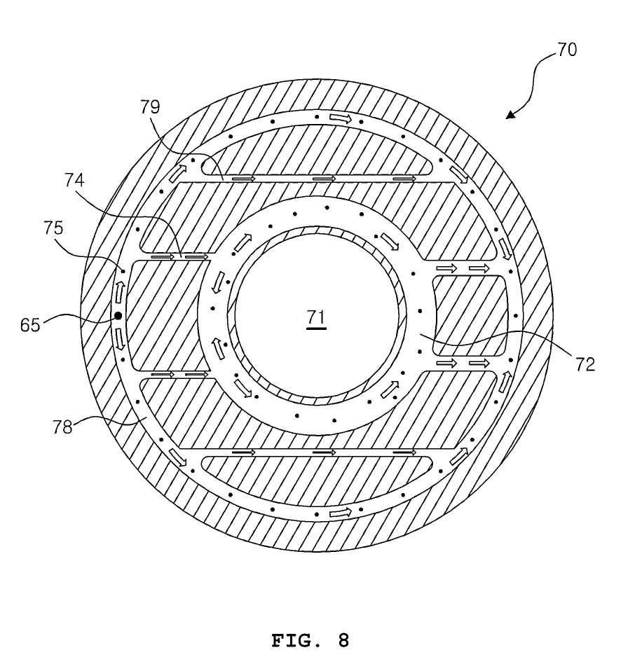

FIG. 8 is a cross-sectional view illustrating a fourth modified example of the block plate of FIG. 1 and a flow of the source gas. Hereinafter, only features different from those according to the foregoing embodiment will be described. Thus, omitted descriptions herein may be substituted for the above-described contents. Unlike FIG. 6, a passage further includes auxiliary connection passages 79. The auxiliary connection passages 79 connects one side of an outer passage 78 adjacent to a gas supply hole 65 with respect to an opening 71 to the other side of an outer passage 78 defined in a side opposite to the gas supply hole 65. The auxiliary connection passages 79 are disposed parallel to each other. A pressure of a source gas within the outer passage may be uniformly regulated through the auxiliary connection passage 79. Connection passages 74 may be disposed parallel to the auxiliary connection passages 79.

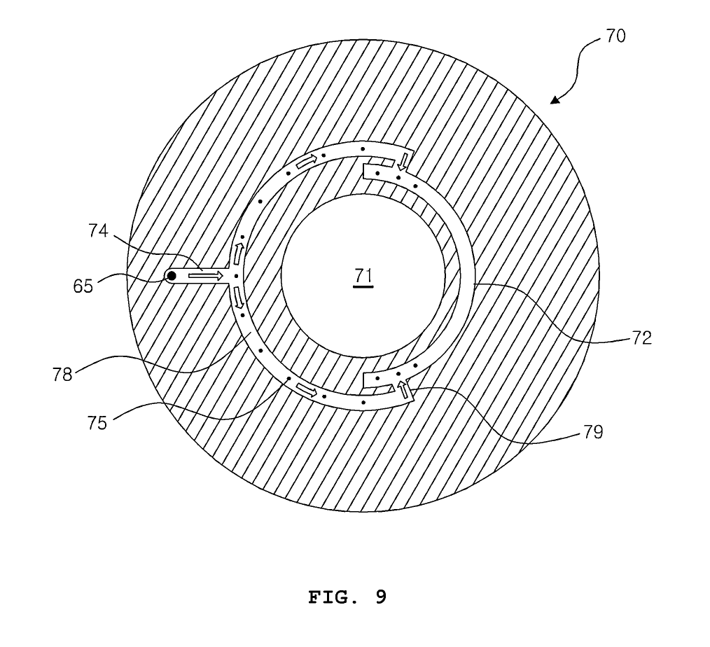

FIG. 9 is a cross-sectional view illustrating a first modified example of the block plate of FIG. 1 and a flow of the source gas. Hereinafter, only features different from those according to the foregoing embodiment will be described. Thus, omitted descriptions herein may be substituted for the above-described contents. Referring to FIG. 9, an inner passage 72 is defined in a side opposite to a gas supply hole 65 with respect to an opening 71. Also, the inner passage 72 may have a semicircular shape. An outer passage 78 may be defined outside the inner passage 72 to maximally approach the inner passage 72. Also, the outer passage may have a semicircular shape and be defined in a side opposite to the inner passage 72 with respect to the opening 71. A connection passage 74 has a linear shape that connects a gas supply hole 65 to the outer passage 78. An auxiliary connection passage 79 connects both ends of the inner passage 72 to both ends of the outer passage 78. Gas spray holes 75 are spaced apart from each other in the inner and outer passages 72 and 78. The gas spray holes 75 may be inclined toward a central portion (or a center) of a substrate W. A source gas moves along the outer passage 78. Then, the source gas moves into the inner passage 72 through the auxiliary connection passage 79. The source gas may move toward the central portion of the substrate W through the gas spray holes 75. Also, the source gas may flow from the central portion toward an edge portion on a surface of the substrate W.

The gas spray holes 75 may have gradually increase in distribution density as the gas spray holes 75 are away from the gas supply hole 65. Also, the gas spray holes 75 may gradually increase in diameter as the gas spray holes 75 are away form the gas supply hole 65. Also, the inner passage 72 may have a width greater than that of the outer passage 78.

According to an embodiment of the present invention, the process uniformity with respect to an entire surface of the substrate may be improved. Also, the plasma generated in the inner space may be improved in density by using the upper and side antennas.

Although the present invention is described in detail with reference to the exemplary embodiments, the invention may be embodied in many different forms. Thus, technical idea and scope of claims set forth below are not limited to the preferred embodiments.

1. A substrate processing apparatus comprising:
a chamber having an opened upper side, the chamber having a passage, through which a substrate is accessible, in a side thereof;
a chamber cover covering the opened upper side of the chamber to provide an inner space in which a process with respect to the substrate is performed, the chamber cover having a gas supply hole passing through a ceiling wall thereof;
an upper antenna disposed on an upper central portion of the chamber cover to generate an electric field in a central portion of the inner space, the upper antenna generating plasma by using a source gas supplied into the inner space;
a side antenna disposed to surround a side portion of the chamber cover to generate an electric field in an edge portion of the inner space, the side antenna generating plasma by using the source gas supplied into the inner space; and
a gas supply tube connected to the gas supply hole to supply the source gas into the inner space,
wherein the gas supply hole is disposed outside the upper antenna.

2. The substrate processing apparatus of claim 1, further comprising a ring-shaped block plate that is closely attached to a ceiling surface of the chamber cover to diffuse the source gas toward the substrate,
wherein the block plate comprises:
an opening defined in a center thereof to correspond to the upper antenna;
a passage recessed from one surface thereof to face the ceiling surface; and
a plurality of gas spray holes communicating with the passage to spray the source gas.

3. The substrate processing apparatus of claim 2, wherein the passage comprises:
an inner passage defined along a circumference of the opening to correspond to a central portion of the substrate; and
a connection passage connecting the gas supply hole to the inner passage,
wherein the gas spray holes are defined in an inner circumferential surface of the block plate.

4. The substrate processing apparatus of claim 2, wherein the passage comprises:
an inner passage defined along a circumference of the opening to correspond to a central portion of the substrate; and
a connection passage connecting the gas supply hole to the inner passage,
wherein the gas spray holes are spaced apart from each other in the inner passage.

5. The substrate processing apparatus of claim 3, wherein the gas spray holes gradually increase in distribution density as the gas spray holes are away from the gas supply hole.

6. The substrate processing apparatus of claim 3, wherein the gas spray holes gradually increase in diameter as the gas spray holes are away from the gas supply hole.

7. The substrate processing apparatus of claim 2, wherein the passage comprises:
an inner passage defined along a circumference of the opening to correspond to a central portion of the substrate;
an outer passage defined outside the inner passage; and
a plurality of connection passages connecting the inner passage to the outer passage,
wherein the gas supply hole is defined in the outer passage, and the gas spray holes are respectively defined in the inner passage and the outer passage.

8. The substrate processing apparatus of claim 7, wherein the connection passages gradually increase in width as the connection passages are away from the gas supply hole.

9. The substrate processing apparatus of claim 7, wherein the gas spray holes defined in the inner passage have distribution densities greater than those of the gas spray holes defined in the outer passage.

10. The substrate processing apparatus of claim 7, wherein the gas spray holes defined in the inner passage have diameters greater than those of the gas spray holes in the outer passage.

11. The substrate processing apparatus of claim 2, wherein the passage comprises:
an inner passage defined along a circumference of the opening to correspond to a central portion of the substrate;
an outer passage defined outside the inner passage; and
a plurality of connection passages connecting the inner passage to the outer passage,
wherein the gas supply hole is defined in the outer passage, and the gas spray holes are respectively defined in an inner circumferential surface of the block plate and the outer passage.

12. The substrate processing apparatus of claim 7, wherein the passage further comprises a plurality of auxiliary connection passages connecting one side of the outer passage defined in a side opposite to the gas supply hole with respect to the opening to the other side of the outer passage adjacent to the gas supply hole, the plurality of auxiliary connection passages being defined parallel to each other,
wherein the connection passages are parallel to the auxiliary connection passages.

13. The substrate processing apparatus of claim 2, wherein the passage comprises:
an inner passage defined along a circumference of the opening to correspond to a central portion of the substrate, the inner passage having a semicircular shape and being defined in a side opposite to the gas supply hole with respect to the opening;
an outer passage defined outside the inner passage, the outer passage having a semicircular shape and being defined in a side opposite to the inner passage with respect to the opening;
a connection passage having one end connected to the gas supply hole and the other end connected to a central portion of the outer passage; and
an auxiliary connection passage connecting both ends of the inner passage to both ends of the outer passage,
wherein the gas spray holes are spaced apart from each other in the inner passage and the outer passage.

14. The substrate processing apparatus of claim 4, wherein the gas spray holes gradually increase in distribution density as the gas spray holes are away from the gas supply hole.

15. The substrate processing apparatus of claim 4, wherein the gas spray holes gradually increase in diameter as the gas spray holes are away from the gas supply hole.

16. The substrate processing apparatus of claim 8, wherein the passage further comprises a plurality of auxiliary connection passages connecting one side of the outer passage defined in a side opposite to the gas supply hole with respect to the opening to the other side of the outer passage adjacent to the gas supply hole, the plurality of auxiliary connection passages being defined parallel to each other,
wherein the connection passages are parallel to the auxiliary connection passages.

17. The substrate processing apparatus of claim 9, wherein the passage further comprises a plurality of auxiliary connection passages connecting one side of the outer passage defined in a side opposite to the gas supply hole with respect to the opening to the other side of the outer passage adjacent to the gas supply hole, the plurality of auxiliary connection passages being defined parallel to each other,
wherein the connection passages are parallel to the auxiliary connection passages.

18. The substrate processing apparatus of claim 10, wherein the passage further comprises a plurality of auxiliary connection passages connecting one side of the outer passage defined in a side opposite to the gas supply hole with respect to the opening to the other side of the outer passage adjacent to the gas supply hole, the plurality of auxiliary connection passages being defined parallel to each other,
wherein the connection passages are parallel to the auxiliary connection passages.

19. The substrate processing apparatus of claim 11, wherein the passage further comprises a plurality of auxiliary connection passages connecting one side of the outer passage defined in a side opposite to the gas supply hole with respect to the opening to the other side of the outer passage adjacent to the gas supply hole, the plurality of auxiliary connection passages being defined parallel to each other,
wherein the connection passages are parallel to the auxiliary connection passages.
